(19) United States
(12) Patent Application Publication
(10) Pub. No.: US 2025/0201794 A1
(43) Pub. Date: Jun. 19, 2025

(54) SEMICONDUCTOR PACKAGE

(71) Applicant: SAMSUNG ELECTRONICS CO., LTD., Suwon-si (KR)

(72) Inventors: Haseob SEONG, Suwon-si (KR); Dawoon JUNG, Suwon-si (KR)

(73) Assignee: SAMSUNG ELECTRONICS CO., LTD., Suwon-si (KR)

(21) Appl. No.: 18/782,841

(22) Filed: Jul. 24, 2024

(30) Foreign Application Priority Data
Dec. 13, 2023 (KR) 10-2023-0181092

(51) Int. Cl. H01L 25/18; H01L 23/00; H01L 23/16; H01L 23/31; H10B 80/00

(52) U.S. Cl. CPC H01L 25/18; H01L 23/16; H01L 23/3135; H01L 24/08; H01L 2224/08145; H01L 2225/06541; H01L 2924/1431; H01L 2924/1434; H10B 80/00

(57) ABSTRACT

Provided is a semiconductor package including a chip stack including first semiconductor chips, and a second semiconductor chip on an uppermost first semiconductor chip, an upper cover member on the chip stack, an intermediate insertion member between the upper cover member and the chip stack, and a dam structure on the base chip around the chip stack, the intermediate insertion member having a lower surface contacting the second semiconductor chip, an upper surface contacting the upper cover member, and a side surface between the lower surface and the upper surface, at least a portion of the side surface of the intermediate insertion member being curved, a height of the dam structure being greater than a height of the chip stack, and a thickness of the upper cover member being greater than a thickness of the first semiconductor chips and a thickness of the second semiconductor chip.

### CROSS-REFERENCE TO RELATED APPLICATION

This application claims priority to Korean Patent Application No. 10-2023-0181092 filed on Dec. 13, 2023, in the Korean Intellectual Property Office, the disclosure of which is incorporated herein by reference in its entirety.

### BACKGROUND

Embodiments of the present disclosure relate to a semiconductor package.

A semiconductor device mounted on an electronic device requires high performance and high capacity along with miniaturization. In order to implement this, a semiconductor package for interconnecting semiconductor chips stacked in a vertical direction using a through-electrode (e.g., through-silicon via) has been developed.

### SUMMARY

One or more embodiments provide a semiconductor package having improved reliability.

According to an aspect of one or more embodiments, there is provided a semiconductor package including a base chip including a lower connection terminal and an upper connection terminal opposite to each other and a through-electrode connecting the lower connection terminal and the upper connection terminal, a chip stack stacked on the base chip in a first direction, the chip stack including a plurality of first semiconductor chips including a first lower pad and a first upper pad opposite to each other, and a through-via connecting the first lower pad and the first upper pad, and a second semiconductor chip on an uppermost first semiconductor chip, among the plurality of first semiconductor chips, the second semiconductor chip including a second lower pad connected to the through-via, an upper cover member on the chip stack, an intermediate insertion member between the upper cover member and the chip stack, a dam structure on the base chip on a side surface of the chip stack, a molded layer on at least a portion of each of the chip stack, the intermediate insertion member, the upper cover member, and the dam structure on the base chip, and a connection bump below the base chip and connected to the lower connection terminal, wherein the first lower pad included in each of the plurality of first semiconductor chips is in contact with the upper connection terminal included in the base chip in the first direction or the first upper pad included in each of the plurality of first semiconductor chips in the first direction, wherein the second lower pad of the second semiconductor chip is in contact with the first upper pad of the uppermost first semiconductor chip in the first direction, wherein the intermediate insertion member has a lower surface in contact with the second semiconductor chip, an upper surface in contact with the upper cover member, and a side surface between the lower surface and the upper surface, wherein at least a portion of the side surface of the intermediate insertion member is curved, wherein a height of the dam structure in the first direction is greater than a height of the chip stack in the first direction, and wherein a thickness of the upper cover member in the first direction is greater than a thickness of each of the plurality of first semiconductor chips in the first direction and a thickness of the second semiconductor chip in the first direction.

According to another aspect of one or more embodiments, there is provided a semiconductor package including a base chip including a through-electrode, a plurality of first semiconductor chips stacked on the base chip in a first direction and including a through-via connected to the through-electrode and connected to each other in the first direction, a second semiconductor chip on an uppermost first semiconductor chip, among the plurality of first semiconductor chips, the second semiconductor chip including a lower pad connected to the through-via, an intermediate insertion member and an upper cover member sequentially on the second semiconductor chip in the first direction, and a dam structure on a side surface of each of the plurality of first semiconductor chips, wherein an upper surface of the dam structure is spaced apart from an upper surface of the intermediate insertion member by a first distance in the first direction, and wherein an internal surface of the dam structure is spaced apart from the plurality of first semiconductor chips by a second distance greater than the first distance in a second direction, perpendicular to the first direction.

According to still another aspect of one or more embodiments, there is provided a semiconductor package, including a base chip including a through-electrode, a chip stack stacked on the base chip in a first direction, the chip stack including a plurality of first semiconductor chips including a through-via connected to the through-electrode and connected to each other in the first direction, and a second semiconductor chip on an uppermost first semiconductor chip, among the plurality of first semiconductor chips, the second semiconductor chip including a lower pad connected to the through-via, an intermediate insertion member and an upper cover member sequentially on the chip stack in the first direction, and a dam structure on a side surface of the chip stack, wherein the intermediate insertion member has a lower surface in contact with the chip stack, an upper surface in contact with the upper cover member, and a side surface between the lower surface and the upper surface, and wherein the side surface of the intermediate insertion member includes a first portion extending from the lower surface of the intermediate insertion member at a first slope, and a second portion extending from the first portion to the upper surface of the intermediate insertion member at a second slope less than the first slope.

### BRIEF DESCRIPTION OF DRAWINGS

The above and other aspects, features, and advantages of embodiments will be more clearly understood from the following detailed description, taken in conjunction with the accompanying drawings, in which:

FIG. 1A is a cross-sectional view of a semiconductor package according to one or more embodiments, and FIG. 1B is a partially enlarged view of region ‘A’ of FIG. 1A;

FIG. 2A is a plan view of a semiconductor package according to one or more embodiments, and FIGS. 2B and 2C are views illustrating modified examples of a dam structure according to one or more embodiments;

FIG. 3A is a partially enlarged view of region ‘B’ of FIG. 1A, and FIGS. 3B to 3C are views illustrating modified examples of FIG. 3A;

FIG. 4 is a cross-sectional view of a semiconductor package according to one or more embodiments;

FIG. 5 is a cross-sectional view of a semiconductor package according to one or more embodiments;

FIG. 6 is a cross-sectional view of a semiconductor package according to one or more embodiments;

FIGS. 7A and 7B are views illustrating an modified example of a dam structure;

FIGS. 8A and 8B are cross-sectional views of a semiconductor package according to example embodiments;

FIG. 9A is a plan view of a semiconductor package according to one or more embodiments, and FIG. 9B is a cross-sectional view taken along line II-II′ of FIG. 9A; and

FIGS. 10A to 10E are views illustrating a process of manufacturing a semiconductor package according to one or more embodiments.

### DETAILED DESCRIPTION

The one or more embodiments described herein are examples, and thus, the present disclosure is not limited thereto, and may be realized in various other forms. Each of the one or more embodiments provided in the following description is not excluded from being associated with one or more features of another example or another embodiment also provided herein or not provided herein but consistent with the present disclosure. For example, even if matters described in a specific example or example embodiment are not described in a different example or example embodiment thereto, the matters may be understood as being related to or combined with the different example or embodiment, unless otherwise mentioned in descriptions thereof.

In addition, it should be understood that all descriptions of principles, aspects, examples, and one or more embodiments are intended to encompass structural and functional equivalents thereof. In addition, these equivalents should be understood as including not only currently well-known equivalents but also equivalents to be developed in the future, that is, all devices invented to perform the same functions regardless of the structures thereof.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “top,” and “bottom,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, elements described as “below” or “beneath” other elements would then be oriented “above” the other elements. Thus, the term “below” can encompass both an orientation of above and below. The semiconductor device may be otherwise oriented (rotated 90 degrees or at other orientations) and the spatially relative descriptors used herein interpreted accordingly.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. Herein, when a term “same” is used to compare a dimension of two or more elements, the term may cover a “substantially same” dimension.

It will be understood that, although the terms “first,” “second,” “third,” “fourth,” etc. may be used herein to describe various elements, these elements should not be limited by these terms. These terms are only used to distinguish one element from another element. Thus, a first element discussed below could be termed a second element without departing from the teachings of the present disclosure.

It will be also understood that, even if a certain step or operation of manufacturing an apparatus or structure is described later than another step or operation, the step or operation may be performed later than the other step or operation unless the other step or operation is described as being performed after the step or operation.

Herein, a direction parallel to a main surface of the chip stack CS may be referred to as a horizontal direction (X direction and/or Y direction), and a direction perpendicular to the horizontal direction (X direction and/or Y direction) may be referred to as a vertical direction (Z direction).

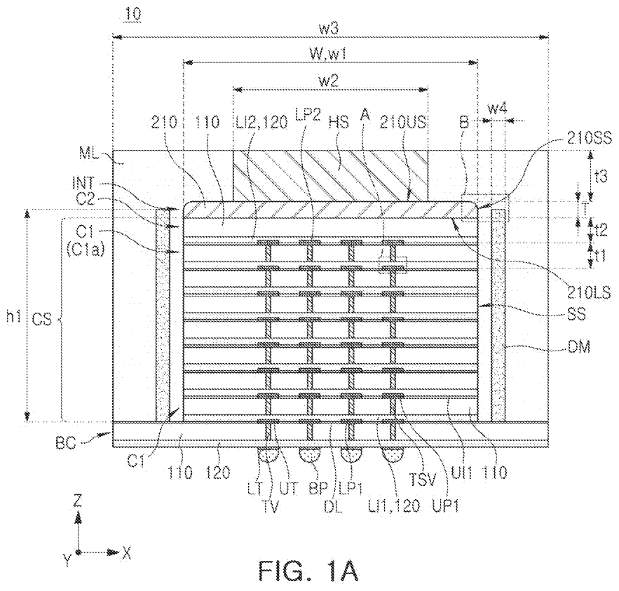

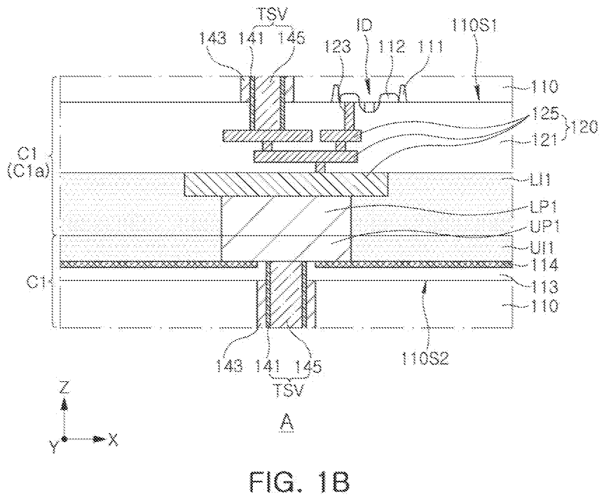

FIG. 1A is a cross-sectional view of a semiconductor package 10 according to one or more embodiments, and FIG. 1B is a partially enlarged view of region ‘A’ of FIG. 1A.

Referring to FIGS. 1A and 1B, a semiconductor package 10 according to one or more embodiments may include a base chip BC, a chip stack CS, a dam structure DM, an intermediate insertion member INT, and an upper cover member HS. According to one or more embodiments, the semiconductor package 10 may further include a molded layer ML and/or a plurality of connection bumps BP.

The chip stack CS may include a plurality of semiconductor chips C1 and C2 stacked in a vertical direction (Z-direction). The chip stack CS may include a plurality of first semiconductor chips C1 stacked on the base chip BC in the first direction (Z-direction), and a second semiconductor chip C2 stacked on an uppermost first semiconductor chip C1a. According to one or more embodiments, the chip stack CS may include a smaller or greater number of semiconductor chips than those illustrated in the drawing. For example, the chip stack CS may include less than or equal to seven or greater than or equal to nine semiconductor chips C1 and C2.

The plurality of first semiconductor chips C1 may include first lower pads LP1 and first upper pads UP1 opposite to each other, and first through-vias TSV1 electrically connecting the first lower pads LP1 and the first upper pads UP1. The first through-vias TSV1 may be electrically connected to through-electrodes TV and may be electrically connected to each other in the vertical direction (Z-direction).

The second semiconductor chip C2 may include second lower pads LP2 electrically connected to the first upper pads UP1 of the uppermost first semiconductor chip C1a. A thickness t2 of the second semiconductor chip C2 may be substantially the same as a thickness t1 of each of the plurality of first semiconductor chips C1 in the vertical direction (Z direction), but embodiments are not limited thereto. According to one or more embodiments, the thickness t2 of the second semiconductor chip C2 may be less than the thickness t1 of each of the plurality of first semiconductor chips C1.

Since the plurality of first semiconductor chips C1 and second semiconductor chips C2 may include substantially identical or similar components, hereinafter, identical or similar components are described using identical or similar terms and/or reference signs. The plurality of first semiconductor chips C1 and the second semiconductor chip C2 may be collectively referred to as semiconductor chips C1 and C2.

The semiconductor chips C1 and C2 include a substrate 110, a circuit layer 120, a lower insulating layer L1, lower pads LP, an upper insulating layer UI, upper pads UP, and/or through-vias TSV. The second semiconductor chip C2 may include the substrate 110, the circuit layer 120, the lower insulating layer L1, and the lower pads LP2. In the present disclosure, the lower insulating layer L1, the lower pads LP, the upper insulating layer UI, the upper pads UP, and/or the through-vias TSV may collectively refer to corresponding first and second components, respectively. For example, the lower insulating layer L1 may refer to both a first lower insulating layer LI1 and a second lower insulating layer LI2, and the lower pads LP may refer to both first lower pads LP1 and second lower pads LP2.

The substrate 110 may be a semiconductor wafer. The substrate 110 may include, for example, a semiconductor element such as silicon (Si) and germanium (Ge), or a compound semiconductor such as silicon carbide (SiC), gallium arsenide (GaAs), indium arsenide (InAs), and indium phosphide (InP). The substrate 110 may include a conductive region 112 and an isolation region 111 formed on a front surface 110S1 of the substrate 110. The conductive region 112 may be, for example, a well doped with impurities or a structure doped with impurities. The isolation region 111 is a device isolation structure having a shallow trench isolation (STI) structure and may include silicon oxide.

The circuit layer 120 may be disposed on the front surface 110S1 of the substrate 110 on which the conductive region 112 is formed. The circuit layer 120 may include individual devices ID, an interlayer insulating layer 121, and a wiring structure 125.

The individual devices ID may be disposed on the front surface 110S1 of the substrate 110. The individual devices ID may include, for example, FET such as planar FET or FinFET, memory devices such as a flash memory, dynamic random-access memory (DRAM), static random-access memory (SRAM), electrically erasable programmable read-only memory (EEPROM), parallel random-access memory (PRAM), magnetoresistive random-access memory (MRAM), ferroelectric random-access memory (FeRAM) and resistive random-access memory (RRAM), logic elements such as AND, OR, and NOT, and various active and/or passive devices such as a system LSI, CIS, and MEMS.

The interlayer insulating layer 121 may be formed to cover the individual devices ID and the wiring structure 125, and may electrically separate the individual devices ID disposed on the substrate 110. The interlayer insulating layer 121 may include flowable oxide (FOX), tonen silazen (TOSZ), undoped silica glass (USG), borosilica glass (BSG), phosphosilaca glass (PSG), borophosphosilica glass (BPSG), plasma enhanced tetra ethyl ortho silicate (PETEOS), fluoride silicate glass (FSG), high density plasma (HDP) oxide, plasma enhanced oxide (PEOX), flowable CVD (FCVD) oxide, or combinations thereof. At least a portion of the interlayer insulating layer 121 surrounding the wiring structure 125 may be comprised of a low dielectric layer. The interlayer insulating layer 121 may be formed using a chemical vapor deposition (CVD) process, a flowable CVD process, or a spin coating process. Depending on the process, a boundary between the interlayer insulating layer 121 and the lower insulating layer L1 may not be clearly distinguished.

The wiring structure 125 may be formed as a multilayer structure including a plurality of wiring patterns and a plurality of vias, formed of, for example, aluminum (Al), gold (Au), cobalt (Co), copper (Cu), nickel (Ni), lead (Pb), tantalum (Ta), te1lurium (Te), titanium (Ti), tungsten (W), or combinations thereof. A barrier film (not illustrated) including titanium (Ti), titanium nitride (TiN), tantalum (Ta), or tantalum nitride (TaN) may be disposed between the wiring pattern or/and via and the interlayer insulating layer 121. The wiring structure 125 may be electrically connected to the conductive region 112 and/or the individual devices ID by an interconnector 123 (e.g., a contact plug).

The lower pads LP may be electrically connected to the wiring structure 125. The lower pads LP may include, for example, at least of copper (Cu), nickel (Ni), gold (Au), silver (Ag), titanium (Ti), titanium nitride (TiN), tantalum (Ta), and tantalum nitride (TaN).

The lower insulating layer L1 may surround side surfaces of the lower pads LP. The lower insulating layer L1 may include, for example, silicon oxide (SiO) or silicon carbonitride (SiCN). The lower insulating layer L1 may form a bonding surface provided for inter-dielectric bonding between the lower pads LP.

The upper pads UP may be electrically connected to the through-vias TSV. The upper pads UP may be electrically connected to the conductive region 112 and/or the wiring structure 125 through the through-vias TSV.

The upper insulating layer UI may surround side surfaces of the upper pads UP. The upper insulating layer UI may include, for example, silicon oxide (SiO) or silicon carbonitride (SiCN). The upper insulating layer UI may form a bonding surface provided for inter-dielectric bonding between the upper pads UP.

The through-vias TSV may penetrate through the substrate 110 to electrically connect the lower pads LP (or the wiring structure 125) and the upper pads UP. The through-vias TSV may include a via plug 145 and a side barrier layer 141 surrounding a side surface of the via plug 145. The via plug 145 may include, for example, tungsten (W), titanium (Ti), aluminum (Al), or copper (Cu), and may be formed in a plating process, a PVD process, or a CVD process. The side barrier layer 141 may include titanium (Ti), titanium nitride (TiN), tantalum (Ta), or tantalum nitride (TaN) and may be formed in a plating process, a PVD process or a CVD process. A side insulating film 143 including an insulating material such as silicon oxide, silicon nitride, or silicon oxynitride (e.g., HARP oxide) may be formed between the side barrier layer 141 and the substrate 110.

The through-vias TSV may penetrate through an insulating protective layer 113 formed on a rear surface 110S2 of the substrate 110. The insulating protective layer 113 may include, for example, silicon oxide (SiO), silicon nitride (SiN), silicon carbide (SiC), silicon oxynitride (SiON), or silicon carbonitride (SiCN). A buffer film 114, such as a polishing-stop layer or a barrier, may be disposed on the insulating protective layer 113. For example, the buffer film may include silicon nitride, silicon carbide, silicon oxynitride, or silicon carbonitride.

In example embodiments, the base chip BC, the plurality of first semiconductor chips C1, and the second semiconductor chip C2 may be bonded and coupled to each other by inter-metal bonding and inter-dielectric bonding.

Each of the plurality of first semiconductor chips C1 may include a first lower insulating layer LI1 surrounding the first lower pads LP1 and a first upper insulating layer UI1 surrounding the first upper pads UP1. The second semiconductor chip C2 may include a second lower insulating layer LI2 surrounding the second lower pads LP2.

The first lower insulating layer LI1 of each of the plurality of first semiconductor chips C1 may be in contact with a dielectric layer DL of the base chip BC adjacent thereto in the vertical direction (Z-direction) and the first upper insulating layer UI1 of each of the plurality of first semiconductor chips C1 adjacent thereto in the vertical direction (Z-direction). The second lower insulating layer LI2 of the second semiconductor chip C2 may be in contact with a first upper insulating layer UI1 of the uppermost first semiconductor chip C1a adjacent thereto in the vertical direction (Z-direction).

The first lower pads LP1 of each of the plurality of first semiconductor chips C1 may be in contact with upper connection terminals UT of the base chip BC adjacent thereto in the vertical direction (Z-direction) and the first upper pads UP1 of each of the plurality of first semiconductor chips C1 adjacent thereto in the vertical direction (Z-direction). The second lower pads LP2 of the second semiconductor chip C2 may be in contact with first upper pads UP1 of the uppermost first semiconductor chip C1a adjacent thereto in the first direction (Z-direction).

The first lower insulating layer LI1, the first upper insulating layer UI1, the second lower insulating layer LI2, and the dielectric layer DL include at least one of silicon oxide (SiO) and silicon carbonitride (SiCN).

The intermediate insertion member INT may be disposed between the chip stack CS and the upper cover member HS. The intermediate insertion member INT may be in contact with the second semiconductor chip C2 and the upper cover member HS of the chip stack CS. The intermediate insertion member INT may be bonded and coupled to the second semiconductor chip C2 and the upper cover member HS through inter-dielectric bonding. For example, the intermediate insertion member INT may include a body 210 defining a lower surface 210LS in contact with the second semiconductor chip C2 and an upper surface 210US in contact with the upper cover member HS. The body 210 of the intermediate insertion member INT may include a material that may be bonded and coupled to the substrate 110 of the second semiconductor chip C2. For example, the body 210 of the intermediate insertion member INT may include a semiconductor material such as silicon (Si) or germanium (Ge). For example, the intermediate insertion member INT may be a silicon dummy electrically insulated from the chip stack CS, but embodiments are not limited thereto. According to example embodiments, on the lower surface 210LS of the body 210 in contact with the second semiconductor chip C2, a bonding layer including at least one of silicon oxide (SiO) and silicon carbonitride (SiCN) may be formed.

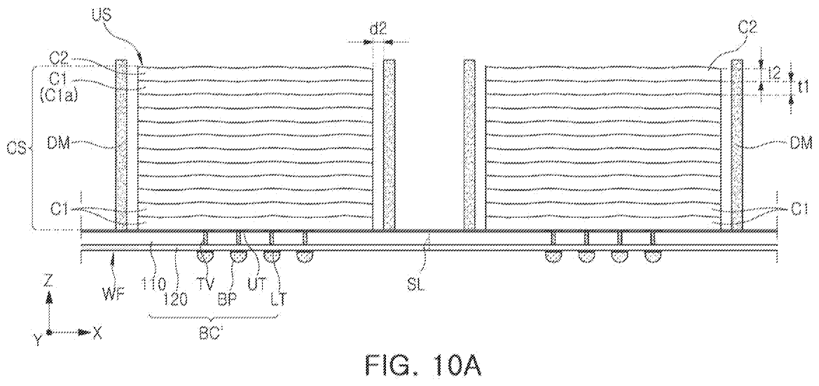

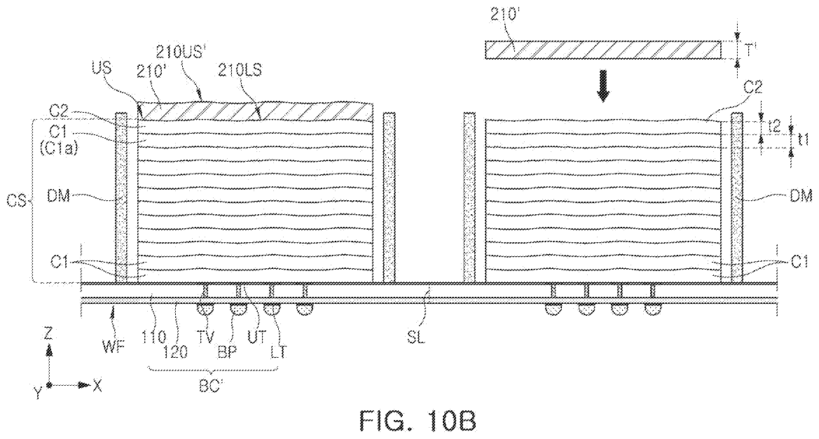

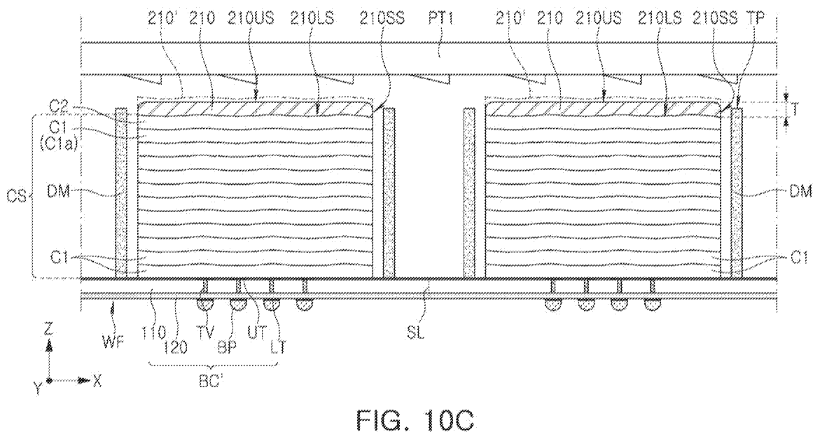

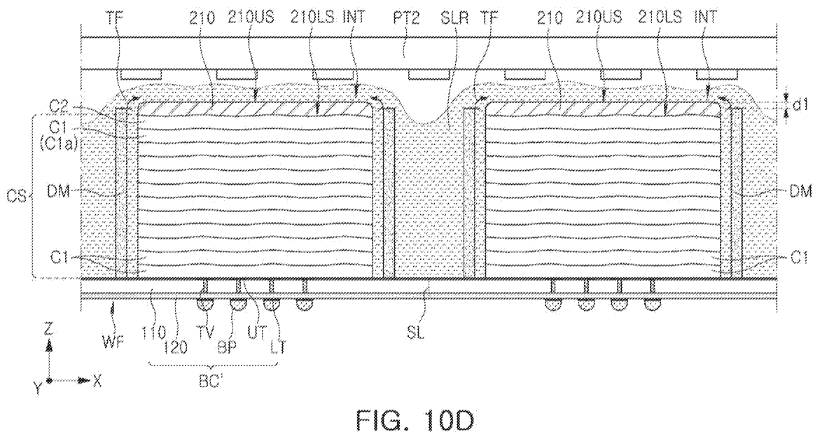

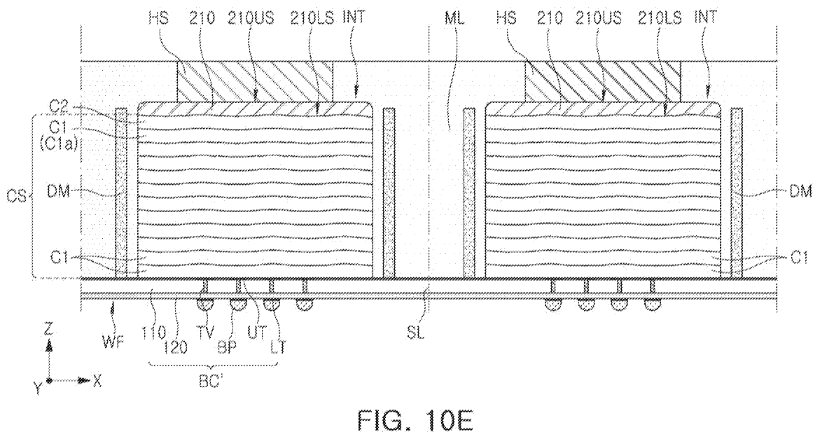

The intermediate insertion member INT may remove a surface topology accumulated by the plurality of first semiconductor chips C1 and the second semiconductor chip C2, thereby improving the bonding quality and reliability of the upper cover member HS, which has a thickness greater than a thickness of the semiconductor chips C1 and C2 in the vertical direction (Z direction). The intermediate insertion member INT may have a lower surface 210LS in contact with the second semiconductor chip C2 and an upper surface 210US in contact with the upper cover member HS. The lower surface 210LS of the intermediate insertion member INT may be a wave surface in contact with an upper surface of the second semiconductor chip C2 on which the surface topology of the semiconductor chips C1 and C2 is accumulated, but the upper surface 210US of the intermediate insertion member INT may be a flat surface to which a flattening process has been applied. This will be described in more detail with reference to FIGS. 10A to 10E.

In example embodiments, the upper surface 210US of the intermediate insertion member INT has an edge thereof polished, and accordingly, in some regions, it may not be possible to provide a flat surface required for bonding of the upper cover member HS. For example, at least a portion of a side surface 210SS of the intermediate insertion member INT that is close to an outer periphery of the upper surface 210US of the intermediate insertion member INT may be a curved surface. Accordingly, the upper cover member HS may have a smaller planar area than a planar area of the intermediate insertion member INT. For example, a width W of the intermediate insertion member INT in a horizontal direction (X-direction) may be greater than a second width w2 of the upper cover member HS. The width W of the intermediate insertion member INT in the horizontal direction (X-direction) may be substantially equal to a first width w1 of the chip stack CS, but embodiments are not limited thereto. A third width w3 of the base chip BC in the horizontal direction (X-direction) may be greater than the first width w1, but embodiments are not limited thereto.

According to one or more embodiments, a thickness T of the intermediate insertion member INT may be less than a thickness t1 of each of the plurality of first semiconductor chips C1 and a thickness t2 of the second semiconductor chip C2 in the vertical direction (Z direction). For example, the thickness T from the lower surface 210LS to the upper surface 210US of the intermediate insertion member INT may be less than the thickness t1 of each of the plurality of first semiconductor chips C1 and the thickness t2 of each of the plurality of second semiconductor chips C2. The thickness T of the intermediate insertion member INT may be about 30 μm or less, and may be in the range of, for example, about 20 μm to about 30 μm, about 15 μm to about 25 μm, or about 10 μm to about 20 μm, but embodiments are not limited thereto.

The upper cover member HS may be disposed on the intermediate insertion member INT. The upper cover member HS may be attached to a flat upper surface 210US of the intermediate insertion member INT. The planar area of the upper cover member HS may be equal to or smaller than the flat upper surface 210US of the intermediate insertion member INT. The upper cover member HS may include a material capable of bonding the intermediate insertion member INT and the dielectric, for example, silicon (Si), but embodiments are not limited thereto. The upper cover member HS may provide a heat dissipation path for the semiconductor package 10, and may adjust an entire height of the semiconductor package 10 in the vertical direction (Z direction). A thickness t3 of the upper cover member HS may be greater than the thickness t1 of each of the plurality of first semiconductor chips C1 and the thickness t2 of the second semiconductor chip C2 in the vertical direction (Z direction).

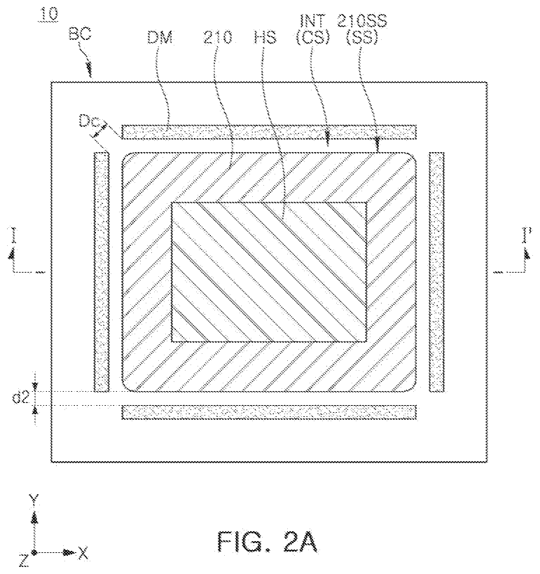

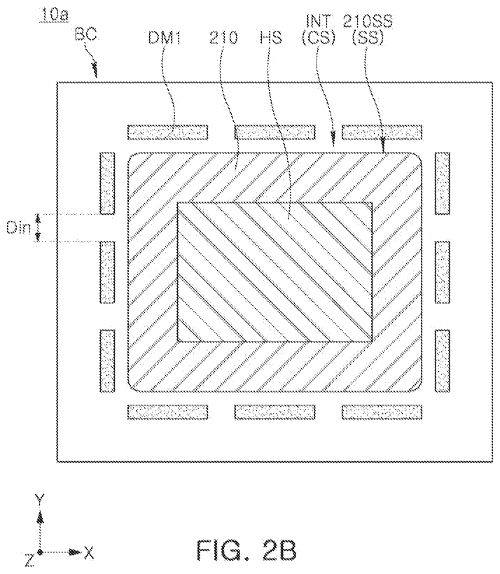

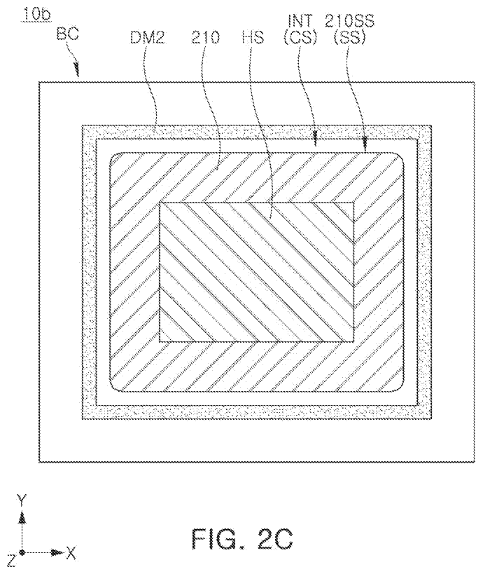

The dam structure DM may be disposed around the chip stack CS. The dam structure DM may be formed by patterning, for example, a thermosetting resin such as an epoxy resin, a thermoplastic resin such as polyimide, or reinforced resins in which inorganic fillers and the like are impregnated into these resins. The dam structure DM may be formed to surround at least a portion of a side surface SS of the chip stack CS. A planar form of the dam structure DM will be described in more detail below with reference to FIGS. 2A to 2C.

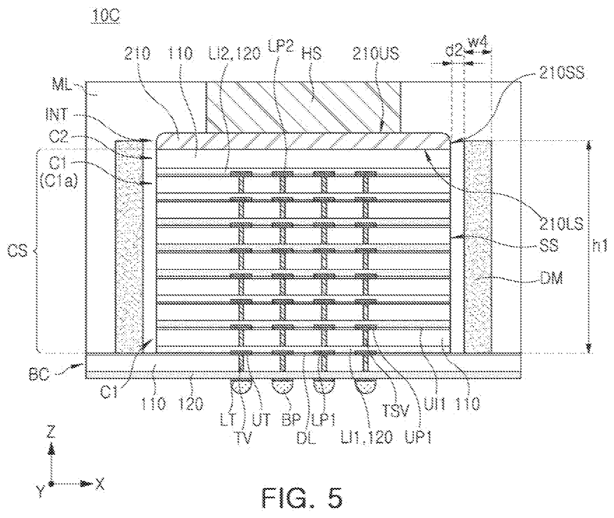

According to one or more embodiments, the dam structure DM may be formed at a predetermined height in order to prevent a slurry from escaping to the outside of the intermediate insertion member INT during a polishing process of the intermediate insertion member INT. A height h1 of the dam structure DM in the vertical direction (Z-direction) may be greater than a height of the chip stack CS in the vertical direction (Z-direction). An upper surface TP of the intermediate insertion member INT may be disposed adjacent to the upper surface 210US of the intermediate insertion member INT. For example, the upper surface TP of the intermediate insertion member INT may be disposed on a level between the upper surface 210US of the intermediate insertion member INT and the lower surface 210LS of the intermediate insertion member INT. For structural stability, a ratio of a width w4 of the dam structure DM in the horizontal direction (X-direction) to the height h1 of the dam structure DM in the vertical direction (Z-direction) may be about 10% or more, and may be in the range of, for example, about 10% to about 40%, about 10% to about 30%, or about 10% to about 20%, but embodiments are not limited thereto. The width w4 of the dam structure DM may be less than a distance between the dam structure DM and the intermediate insertion member INT (‘d2’ in FIG. 2A) in the horizontal direction (X direction), but embodiments are not limited thereto (see FIG. 5).

The base chip BC may be a buffer chip or a control chip including a plurality of logic elements and/or memory elements. For example, the base chip BC may transmit signals from the first semiconductor chips C1 and the second semiconductor chip C2 stacked on top thereof to the outside, and may also transmit signals and power from the outside to the semiconductor chips C1 and C2. The semiconductor chips C1 and C2 may be memory chips including volatile memory devices such as DRAM and SRAM, or non-volatile memory devices such as PRAM, MRAM, FeRAM, or RRAM.

Since the components of the base chip BC have characteristics substantially identical or similar to the components of the semiconductor chips C1 and C2, the identical or similar components are referred to by identical or similar terms and/or reference signs, and overlapping parts are replaced with descriptions of the corresponding components. For example, it may be understood that lower connection terminals LT and upper connection terminals UT of the base chip BC are components corresponding to the lower pads LP and the upper pads UP of the semiconductor chips C1 and C2, the dielectric layer DL of the base chip BC is components corresponding to the lower insulating layer LI and the upper insulating layer UI of the semiconductor chips C1 and C2, and the through-electrodes TV of the base chip BC are components corresponding to the through-vias TSV of the semiconductor chips C1 and C2.

The base chip BC may include lower connection terminals LT and upper connection terminals UT opposite to each other, and through-electrodes TV electrically connecting the lower connection terminals LT and the upper connection terminals UT.

The base chip BC may further include a dielectric layer DL surrounding the upper connection terminals UT. The upper connection terminals UT may be in direct contact with first lower pads LP1 of a lowermost first semiconductor chip C1 adjacent thereto in the vertical direction (Z-direction). The dielectric layer DL may be in direct contact with a first lower insulating layer LI1 of the lowermost first semiconductor chip C1 adjacent thereto in the vertical direction (Z-direction).

The base chip BC may be electrically connected to an external device (e.g., a main board) through a plurality of connection bumps BP. The plurality of connection bumps BP may be disposed below the base chip BC, and may be electrically connected to the lower connection terminals LT. The plurality of connection bumps BP may include, for example, tin (Sn), indium (In), bismuth (Bi), antimony (Sb), copper (Cu), silver (Ag), zinc (Zn), lead. (Pb) and/or alloys thereof. According to one or more embodiments, the plurality of connection bumps BP may have a combination of a conductive pillar and a solder ball.

The molded layer ML may cover at least a portion of each of the chip stack CS, the intermediate insertion member INT, the upper cover member HS, and the dam structure DM on the base chip BC. According to one or more embodiments, an upper surface of the upper cover member HS may be exposed from the molded layer ML. The molded layer ML may be formed of a polymer resin, for example, a thermosetting resin such as an epoxy resin, a thermoplastic resin such as polyimide, or a prepreg, an Ajinomoto Build-up Film (ABF), FR-4, BT, an epoxy molding compound (EMC) in which inorganic fillers and the like are impregnated with in these resins.

Hereinafter, referring to FIGS. 2A to 2C together with FIG. 1A, a planar shape of the dam structure DM will be described in more detail.

FIG. 2A is a plan view of the semiconductor package 10 according to one or more embodiments, and FIGS. 2B and 2C are views illustrating modified examples of a dam structure. FIGS. 2A to 2C illustrate a planar arrangement of components excluding a molded layer ML. For example, FIG. 1A can be understood as a cross-section corresponding to line I-I′ in FIG. 2A.

Referring to FIG. 2A, in one or more embodiments, the dam structure DM may be arranged to surround at least a portion of a side surface SS of the chip stack CS. The dam structure DM may correspond to and face a side surface 210SS of the intermediate insertion member INT and may include a plurality of dam structures DM spaced apart from each other.

The dam structure DM may be spaced apart from the side surface 210SS of the intermediate insertion member INT (or the side surface SS of the chip stack CS by a predetermined distance. A distance d2 between the dam structure DM and the intermediate insertion member INT may be about 100 μm or less, and may be in the range of, for example, about 30 μm to about 100 μm, about 40 μm to about 100 μm, about 50 μm to about 100 μm, about 50 μm to about 90 μm, or about 50 μm to about 80 μm, but embodiments are not limited thereto. When the distance d2 between the dam structure DM and the intermediate insertion member INT exceeds approximately 100 μm, a slurry may not be smoothly supplied during a polishing process.

A separation distance Dc between the plurality of dam structures DM in a corner portion of the intermediate insertion member INT may be about 100 μm or less, and may be in the range of, for example, about 30 μm to about 100 μm, about 40 μm to about 100 μm, about 50 μm to about 100 μm, about 50 μm to about 90 μm, or about 50 μm to about 80 μm, but embodiments are not limited thereto. When the separation distance Dc between the plurality of dam structures DM exceeds about 100 μm, the slurry may not be smoothly supplied during the polishing process. A space between the dam structures DM may provide a path for removal of the slurry after the polishing process, but embodiments are not limited thereto. In FIG. 2A, the corner portion of the intermediate insertion member INT is illustrated as a curved surface to emphasize that a flattening process has been applied to the intermediate insertion member INT, but a planar shape of the intermediate insertion member INT may not be limited thereto. For example, as illustrated in FIG. 1A, a curved surface may be formed only on an upper portion of the intermediate insertion member INT through the flattening process.

Referring to FIG. 2B, in a semiconductor package 10a according to one or more other embodiments, the dam structure DM1 may include a plurality of dam structures DM1 spaced apart from each other along the side surface 210SS of the intermediate insertion member INT. The plurality of dam structures DM1 may be spaced apart from each other in a direction, parallel to the side surface 210SS of the intermediate insertion member INT. An internal separation distance Din between the plurality of dam structures DM1 may be about 100 μm or less, and may be in the range of, for example, about 30 μm to about 100 μm, about 40 μm to about 100 μm, about 50 μm to about 100 μm, about 50 μm to about 90 μm, or about 50 μm to about 80 μm, but embodiments are not limited thereto. When the internal separation distance Din exceeds approximately 100 μm, the slurry may not be smoothly supplied during the polishing process.

Referring to FIG. 2C, in a semiconductor package 10b according to one or more other embodiments, the dam structure DM2 may be formed to continuously surround the side surface 210SS of the intermediate insertion member INT (or the side surface SS of the chip stack CS). The dam structure DM2 may have a planar shape to minimize slurry leakage during the polishing process.

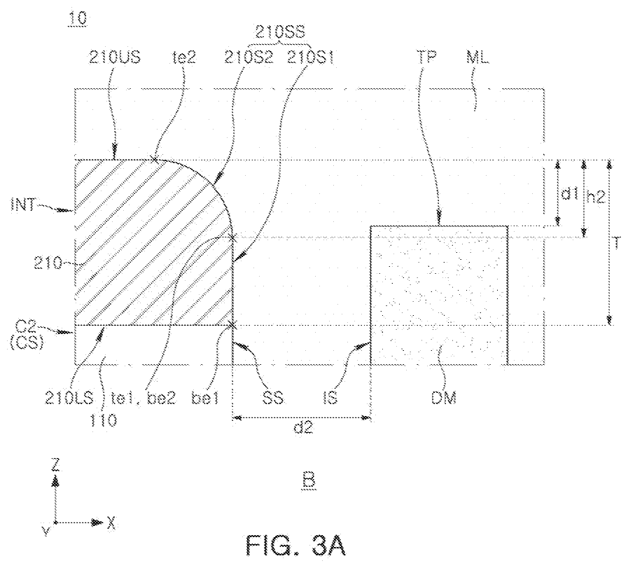

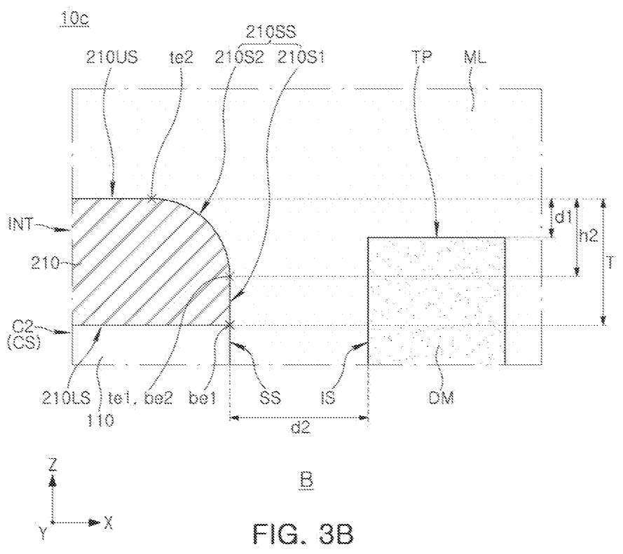

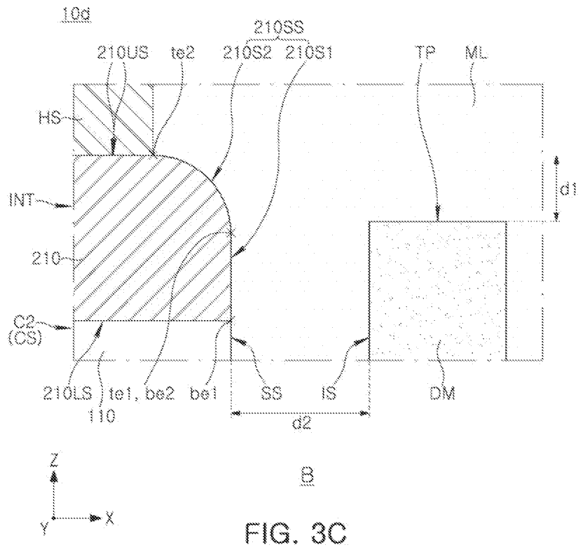

Hereinafter, referring to FIGS. 3A to 3C together with FIG. 1A, a relationship between the intermediate insertion member INT and the structure DM will be described in more detail.

FIG. 3A is a partially enlarged view of region ‘B’ of FIG. 1A, and FIGS. 3B to 3C are view illustrating modified examples of FIG. 3A.

Referring to FIG. 3A, in the semiconductor package 10 according to one or more embodiments, an intermediate insertion member INT may have a lower surface 210LS in contact with a chip stack CS, an upper surface 210US in contact with an upper cover member HS, and a side surface 210SS between a lower surface 201LS and an upper surface 210US. The side surface 210SS of the intermediate insertion member INT may include a first portion 210S1 extending from the lower surface 210LS, and a second portion 210S2 extending from the first portion 210S1 to the upper surface 210US. The first portion 210S1 may extend at a constant slope with respect to the lower surface 210LS of the intermediate insertion member INT. Since the second portion 210S2 is formed in the flattening process, the second portion 210S2 may extend at a constant or continuously changing slope.

For example, the first portion 210S1 may have a first lower end be1 connected to the lower surface 210LS of the intermediate insertion member INT, and a first upper end te1 connected to the second portion 210S2, and may extend at a constant first slope from the first lower end be1 to the first upper end te1. The second portion 210S2 may have a second lower end be2 connected to the first upper end te1, and a second upper end te2 connected to the upper surface 210US of the intermediate insertion member INT, and may extend at a decreasing second slope from the second lower end be2 to the second upper end te2. For example, the second slope of the second portion 210S2 may be smaller than the first slope of the first portion 210S1. For example, a height h2 of the second portion 210S2 may be less than ½ of a thickness T of the intermediate insertion member INT in the vertical direction (Z-direction), but embodiments are not limited thereto.

An upper surface TP of the dam structure DM may be spaced apart from the upper surface 210US of the intermediate insertion member INT by a first distance d1 in the vertical direction (Z-direction) to prevent or reduce the slurry from escaping to the outside of the intermediate insertion member INT during the polishing process of the intermediate insertion member INT. The upper surface TP of the dam structure DM may be disposed on a lower level than the upper surface 210US of the intermediate insertion member INT in the vertical direction (Z-direction). The first distance d1 may be about 10 μm or less, and may be in the range of, for example, about 1 μm to about 10 μm, about 3 μm to about 10 μm, about 5 μm to about 10 μm, or about 7 μm to about 10 μm. When the first distance d1 exceeds about 10 μm, the slurry may not be smoothly supplied during the polishing process, which may cause the bonding quality of the upper cover member HS to deteriorate.

An internal surface IS of the dam structure DM may be spaced apart from the side surface SS of the chip stack CS by a second distance d2 in the horizontal direction (X-direction). The second distance d2 may be greater than the first distance d1. In consideration of an alignment margin between the plurality of first semiconductor chips C1 and the second semiconductor chip C2, side surfaces of a plurality of first semiconductor chips C1 and a second semiconductor chip C2 constituting the side surface SS of the chip stack CS may not form a flat vertical surface. As described above, when the distance d2 between the dam structure DM and the chip stack CS exceeds about 100 μm, the slurry may not be smoothly supplied during the polishing process.

Referring to FIG. 3B, in a semiconductor package 10c according to one or more other embodiments, the height h2 of the second portion 210S2 of the side surface 210SS of the intermediate insertion member INT may be more than ½ of the thickness T of the intermediate insertion member INT. In this manner, the thickness T of the intermediate insertion member INT may be minimized, and the semiconductor package 10c may be miniaturized and thinned. According to one or more other embodiments, the side surface 210SS of the intermediate insertion member INT may not include the first portion 210S1 having a constant slope.

Referring to FIG. 3C, in a semiconductor package 10d according to one or more other embodiments, a side surface of the upper cover member HS may be aligned with the second upper end te2 of the second portion 210S2 of the side surface 210SS of the intermediate insertion member INT in the vertical direction (Z-direction). For example, the upper cover member HS may have a planar area that is substantially the same as or smaller than the flat upper surface 210US of the intermediate insertion member INT.

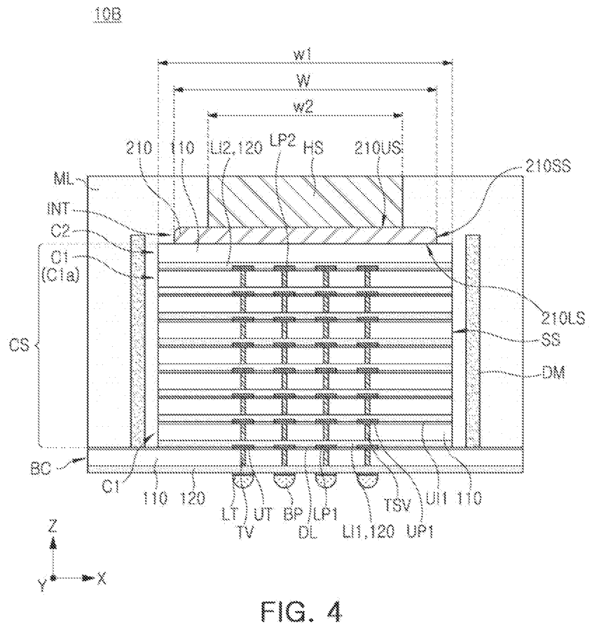

FIG. 4 is a cross-sectional view of a semiconductor package 10B according to one or more embodiments.

Referring to FIG. 4, a semiconductor package 10B of one or more embodiments may have features identical or similar to those described with reference to FIGS. 1A to 3C, except that a width W of the intermediate insertion member INT is smaller than a width w1 of the chip stack CS. According to one or more embodiments, in order to remove a surface topology of the chip stack CS, a flattening process may be applied to the intermediate insertion member INT. In order to ensure bonding stability between the intermediate insertion member INT and the second semiconductor chip C2 during the fattening process, the intermediate insertion member INT may have a size (area, width, etc.) that is at least substantially the same as an area of the second semiconductor chip C2. However, in consideration of an alignment margin of the intermediate insertion member INT and the second semiconductor chip C2, a first portion 210S1 of the side surface 210SS of the intermediate insertion member INT and a side surface of the second semiconductor chip C2 may not form the same vertical plane.

FIG. 5 is a cross-sectional view of a semiconductor package 10C according to one or more embodiments.

Referring to FIG. 5, a semiconductor package 10C of one or more embodiments may have features identical or similar to those described with reference to FIGS. 1A to 4, except that a width w4 of a dam structure DM is increased. In one or more embodiments, the width w4 of the dam structure DM may be equal to or greater than a distance d2 between the dam structure DM and the chip stack CS. When the width w4 of the dam structure DM increases, an effect of preventing the slurry from being separated in the polishing process may be increased.

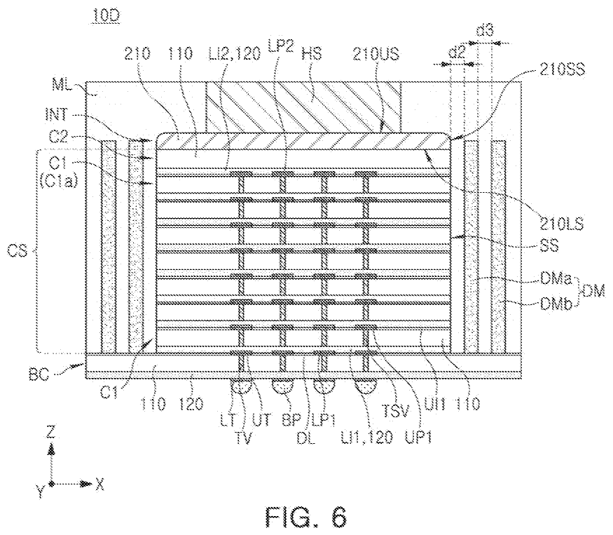

FIG. 6 is a cross-sectional view of a semiconductor package 10D according to one or more embodiments.

Referring to FIG. 6, a semiconductor package 10D of one or more embodiments may have features identical or similar to those described with reference to FIGS. 1A to 5, except that the semiconductor package 10D includes a plurality of dam structures DMa and DMb sequentially arranged and spaced apart from each other in a direction normal to a side surface SS of a chip stack CS. The dam structure DM of the one or more embodiments may include an internal dam structure DMa adjacent to the side surface SS of the chip stack CS, and an external dam structure DMb disposed farther from the chip stack CS than the internal dam structure DMa in the horizontal directions (X-direction and Y-direction).

The internal dam structure DMa may secure an alignment margin of the plurality of first semiconductor chips C1, the second semiconductor chip C2, and the intermediate insertion member INT, and may be disposed to minimize slurry escaping during the polishing process. The distance d2 between the internal dam structure DMa and the intermediate insertion member INT (or the chip stack CS) may be, for example, about 100 μm or less, and may be in the range of, for example, about 30 μm to about 100 μm, about 40 μm to about 100 μm, about 50 μm to about 100 μm, about 50 μm to about 90 μm, or about 50 μm to about 80 μm, but embodiments are not limited thereto. When the distance d2 between the internal dam structure DMa and the intermediate insertion member INT exceeds approximately 100 μm, the slurry may not be smoothly supplied during the polishing process of the intermediate insertion member INT.

The external dam structure DMb may be disposed in a position in which it is easier to form turbulent flow of the slurry during the polishing process. Accordingly, a distance d3 between the external dam structure DMb and the internal dam structure DMa may be equal to or smaller than the distance d2 between the internal dam structure DMa and the chip stack CS.

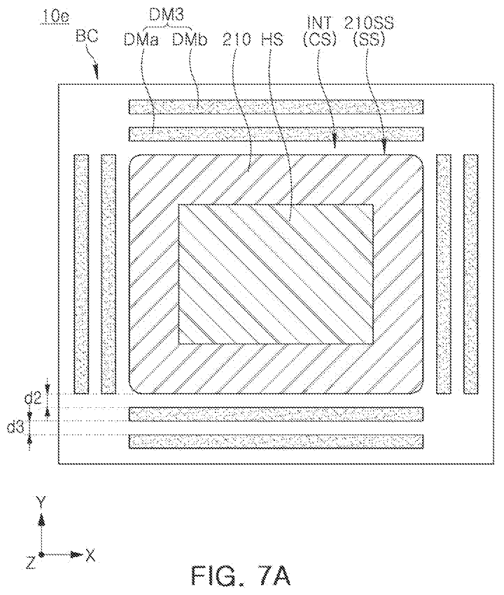

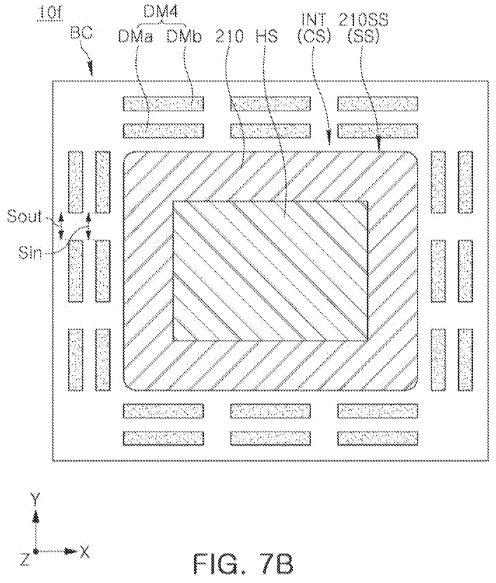

Hereinafter, with reference to FIGS. 7A and 7B together with FIG. 6, a plan form of the dam structure DM of one or more embodiments will be described in more detail.

FIGS. 7A and 7B are views illustrating dam structures DM3 and DM4 according to one or more other embodiments.

Referring to FIG. 7A, in a semiconductor package 10e according to one or more other embodiments, a dam structure DM3 may include an internal dam structure DMa and an external dam structure DMb surrounding at least a portion of a side surface 210SS of an intermediate insertion member INT.

The internal dam structure DMa may correspond to and face the side surface 210SS of the intermediate insertion member INT and may include a plurality of internal dam structures DMa spaced apart from each other. The plurality of internal dam structures DMa may be spaced apart from the side surface 210SS of the corresponding intermediate insertion member (INT) by about 100 μm or less. When the distance d2 between the plurality of internal dam structures DMa and the intermediate insertion member INT exceeds about 100 μm, the slurry may not be smoothly supplied during the polishing process.

The external dam structure DMb may correspond to a plurality of internal dam structures DMa, and may include a plurality of external dam structures DMb spaced apart from each other. The distance d3 between the plurality of external dam structures DMb and the plurality of internal dam structures DMa corresponding to each other may be less than the distance d2 between the plurality of internal dam structures DMa and the intermediate insertion member INT.

Referring to FIG. 7B, in a semiconductor package 10f according to one or more other embodiments, the internal dam structure DMa and the external dam structure DMb of the dam structure DM4 may include a plurality of internal dam structures DMa and a plurality of external dam structures DMb, respectively, which are spaced apart from each other in a direction, parallel to the side surface 210SS of the intermediate insertion member INT.

An internal separation space (Sin) between the plurality of internal dam structures DMa and an external separation space (Sout) between the plurality of external dam structures (DMb) may overlap each other at least partially in horizontal directions (X-direction and Y-direction). For example, the internal separation space (Sin) between the plurality of internal dam structures (DMa) disposed in the horizontal direction (Y-direction) and the external separation space (Sout) between the plurality of external dam structures (DMb) disposed in the third direction (Y-direction) may overlap at least partially in the first direction (X-direction).

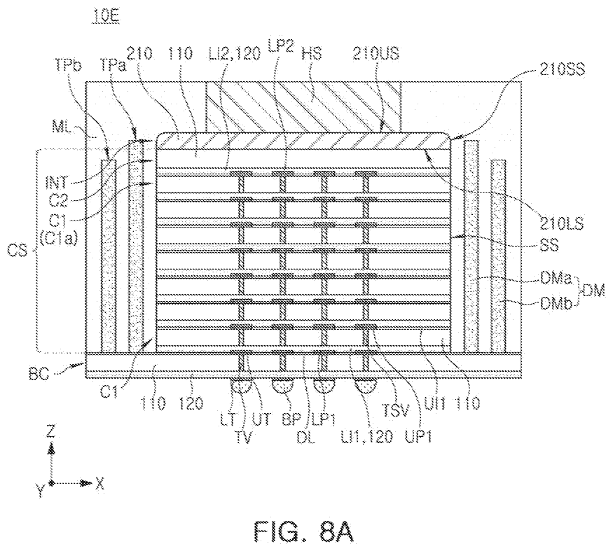

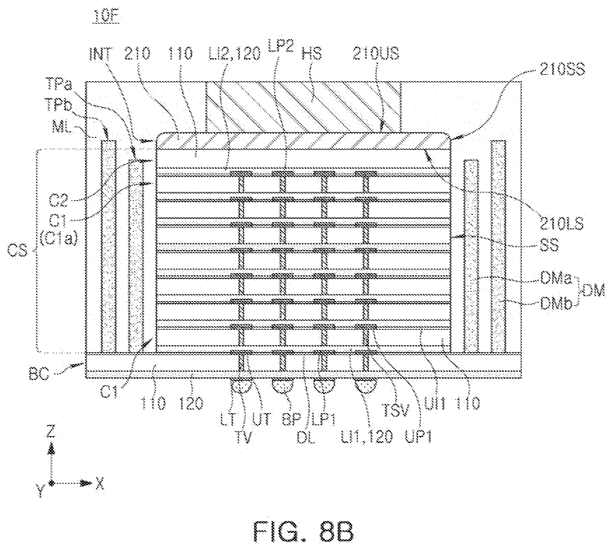

FIGS. 8A and 8B are cross-sectional views of semiconductor packages 10E and 10F according to one or more embodiments.

Referring to FIGS. 8A and 8B, semiconductor packages 10E and 10F according to one or more embodiments may have features identical or similar to those described with reference to FIGS. 1A to 7B, except that the semiconductor packages 10E and 10F include dam structures having different heights DMa and DMb.

A dam structure DM may include an internal dam structure DMa and an external dam structure DMb having different heights in the vertical direction (Z-direction). An upper surface TPa of the internal dam structure DMa and an upper surface TPb of the external dam structure DMb may be disposed on different levels. For example, as illustrated in FIG. 8A, the upper surface (TPa) of the internal dam structure DMa may be disposed on a higher level than the upper surface TPb of the external dam structure DMb. For example, as illustrated in FIG. 8B, the upper surface TPa of the internal dam structure DMa may be disposed on a lower level than the upper surface TPb of the external dam structure DMb. The internal dam structure DMa and the external dam structure DMb may be formed to have a height difference that facilitates generating slurry turbulence in a polishing process described below.

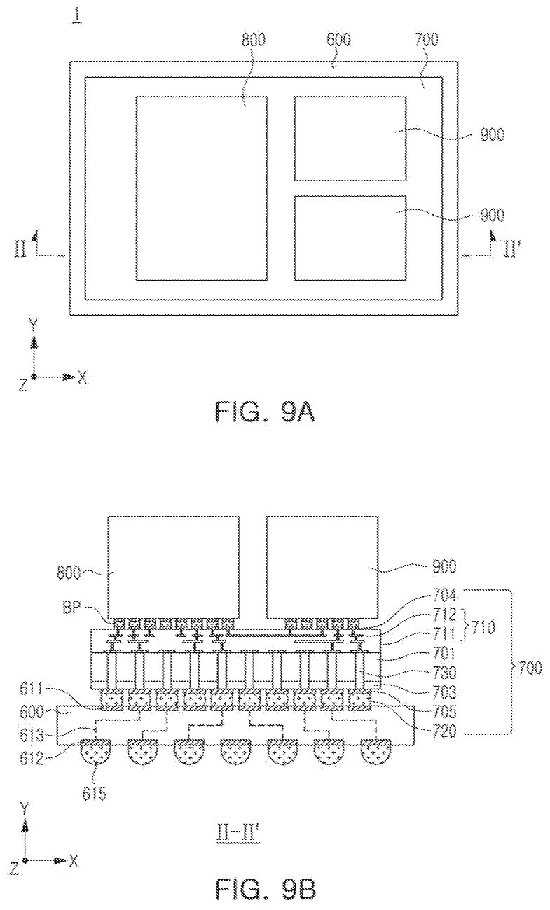

FIG. 9A is a plan view of a semiconductor package 1 according to one or more embodiments, and FIG. 9B is a cross-sectional view taken along line II-II′ of FIG. 9A.

Referring to FIGS. 9A and 9B, a semiconductor package 1 of one or more embodiments may include a package substrate 600, an interposer substrate 700, a first chip structure 800, and a second chip structure 900.

The first chip structure 800 may include a logic chip such as, for example, a central processor (CPU), a graphics processor (GPU), a field programmable gate array (FPGA), a digital signal processor, an encryption processor, a microprocessor, a microcontroller, an analog-to-digital converter, an ASIC, and the like.

The second chip structure 900 may be a semiconductor package structure with characteristics identical or similar to the semiconductor packages 10, 10a, 10b, 10c, 10d, 10e, 10f, 10A, 10B, 10C, 10D, 10E, and 10F described with reference to FIGS. 1A to 8B. For example, the second chip structure 900 may include a high-capacity memory device such as a high bandwidth memory (HBM).

The package substrate 600 is a support substrate on which the interposer substrate 700 is mounted, and may be a substrate for a semiconductor package including a printed circuit board (PCB), a ceramic substrate, a glass substrate, and a tape wiring substrate. The package substrate 600 may include a lower pad 612, an upper pad 611, and a wiring circuit 613. An external connection bump 615 connected to a lower pad 612 may be disposed on a lower surface of the package substrate 600. The external connection bump 615 may include, for example, a solder ball.

The interposer substrate 700 may include a semiconductor substrate 701, a lower protective layer 703, a lower pad 705, an interconnection structure 710, a conductive bump 720, and a through-silicon via 730. The first chip structure 800 and the second chip structure 900 may be electrically connected to each other via the interposer substrate 700.

The semiconductor substrate 701 may be formed of, for example, any one of silicon, organic, plastic, and glass substrates. When the semiconductor substrate 701 is a silicon substrate, the interposer substrate 700 may be referred to as a silicon interposer. When the semiconductor substrate 701 is an organic substrate, the interposer substrate 700 may be referred to as a panel interposer.

The lower protective layer 703 may be disposed on a lower surface of the semiconductor substrate 701, and the lower pad 705 may be disposed below the lower protective layer 703. The lower pad 705 may be connected to the through-silicon via 730. The interposer substrate 700 may be electrically connected to the package substrate 600 through the conductive bumps 720 disposed below the lower pad 705.

The interconnection structure 710 may be disposed on an upper surface of the semiconductor substrate 701, and may include an interlayer insulating layer 711 and a single-layer or multilayer wiring structure 712. When the interconnection structure 710 has a multilayer wiring structure, wiring patterns of different layers may be connected to each other through contact vias. The first semiconductor chip structure 800 and the second semiconductor chip structure 900 may be electrically connected to the upper pad 704 through the connection bumps BP.

The through-silicon via 730 may extend from the upper surface to the lower surface of the semiconductor substrate 701. Furthermore, the through-silicon via 730 may extend to an interior of the interconnection structure 710, and may be electrically connected to the multilayer wiring structure 712. According to one or more embodiments, the interposer substrate 700 may include only an interconnection structure therein and may not include the through-silicon via 730.

The interposer substrate 700 may be used to convert or transmit an input electrical signal between the package substrate 600 and the first chip structure 800 or the second chip structure 900. Accordingly, the interposer substrate 700 may not include devices such as active devices or passive devices. Furthermore, according to one or more embodiments, the interconnection structure 710 may be disposed below the through-silicon via 730. For example, a positional relationship between the interconnection structure 710 and the through-silicon via 730 may be relative.

FIGS. 10A to 10E are views illustrating a process of manufacturing a semiconductor package according to one or more embodiments. FIGS. 10A to 10E briefly illustrate first and second semiconductor chips C1 and C2.

Referring to FIG. 10A, chip stacks CS may be formed on a semiconductor wafer WF. The semiconductor wafer WF may include preliminary base chips BC′ separated by scribe lanes SL. The preliminary base chips BC′ may include the components of a base chip BC described with reference to FIGS. 1A and 1B.

The chip stacks CS may include semiconductor chips C1 and C2 stacked in a vertical direction in a region defined by dam structures DM. The dam structures DM may be formed, for example, by applying and curing a polymer material such as polyimide. The dam structures DM may be spaced apart from corresponding chip stacks CS by a predetermined distance d2. Thicknesses t1 and t2 of the semiconductor chips C1 and C2 may be substantially the same, but embodiments are not limited thereto.

The semiconductor chips C1 and C2 may be bonded to each other by a thermal compression process. The semiconductor chips C1 and C2 may be directly bonded to each other by metal-metal bonding and inter-dielectric bonding (direct bonding) without conductive members (e.g., a solder bump, a copper pillar, etc.) for electrical connection. Since upper surfaces and lower surfaces of each of the semiconductor chips C1 and C2 are directly bonded to each other, the surface topology characteristics of an upper surface US of the second semiconductor chip C2 with surface topology accumulated may be deteriorated. Hereinafter, the semiconductor chips C1 and C2 are briefly illustrated in the drawings, but the semiconductor chips C1 and C2 included in the chip stack CS may be understood as including the components described with reference to FIGS. 1A to 1B.

Referring to FIG. 10B, an intermediate insertion body 210′ may be attached to the chip stacks CS. The intermediate insertion body 210′ may be bonded to the second semiconductor chip C2 in a heat-compression process. Since the intermediate insertion body 210′ is directly bonded to the second semiconductor chip C2, a lower surface 210LS and a temporary upper surface 210U′ of the intermediate insertion body 210′ may have a surface topology corresponding to the second semiconductor chip C2. The surface topology of the semiconductor chips C1 and C2 and the intermediate insertion body 210′ is simplified and illustrated in a unidirectional wave form for convenience of explanation. A thickness T′ of the intermediate insertion body 210′ may be greater than the thicknesses t1 and t2 of the semiconductor chips C1 and C2 in the vertical direction (Z-direction).

Referring to FIG. 10C, a grinding process may be applied to the intermediate insertion body 210′. By partially removing an upper portion of the intermediate insertion body 210′ using a grinding wheel PT1, a body 210 having an upper surface 210US from which the surface topology is removed may be formed. The body 210 may be formed to have a thickness T such that the upper surface 210US is disposed on a level higher than an upper surface TP of the dam structure DM. The lower surface 210LS of the body 210 may be a wave surface having different heights (or multiple ridges), and the upper surface 210US of the body 210 may be a flat surface. Furthermore, a portion of the side surface 210SS of the body 210 may include a curved portion whose slope constantly changes.

Referring to FIG. 10D, a polishing process (e.g., a chemical mechanical planarization (CMP) process) may be applied to the upper surface 210US of the body 210. The upper surface 210US of the body 210 may be polished using a polishing pad PT2 to have a surface roughness Ra of about 0.05 nm or less, for example in the range of about 0.01 nm to about 0.05 nm. The upper surface TP of the dam structure DM may be spaced apart from the upper surface 210US of the body 210 by a distance d1 of about 10 μm or less. The dam structure DM may be disposed adjacent to the chip stack CS to induce turbulence TF of the slurry SLR supplied during the polishing process, and the slurry SLR may be prevented or reduced from being separated from the upper surface 210US of the body 210 by rotating the semiconductor wafer WF and the polishing pad PT2. Accordingly, wheel scratches, water stains, and the like, existing on the upper surface 210US of the body 210, may be more effectively removed. Accordingly, the bonding quality of the upper cover member HS attached in a subsequent process may be improved and the reliability of the semiconductor package may be improved. The slurry SLR entering between the dam structure DM and the chip stack CS may be removed in a subsequent cleaning process. For example, the slurry SLR may be discharged through a separation space between the dam structures DM illustrated in FIG. 2A.

Referring to FIG. 10E, the upper cover member HS may be attached to the intermediate insertion member INT. The upper cover member HS may be closely adhered to and coupled to the upper surface 210US of the intermediate insertion member INT in a heat-compression process. Since the upper cover member HS is stacked on the upper surface 210US of a flattened intermediate insertion member INT, a bonding interface of excellent quality may be formed. Then, a molded layer ML exposing the upper cover member HS may be formed on the semiconductor wafer WF, and a cutting process may be performed along a scribe lane SL to separate individual semiconductor packages.

Embodiments are not limited to the above-described embodiments and the accompanying drawings but is defined by the appended claims and their equivalents. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor package, comprising:
a base chip comprising a lower connection terminal and an upper connection terminal opposite to each other and a through-electrode connecting the lower connection terminal and the upper connection terminal;
a chip stack stacked on the base chip in a first direction, the chip stack comprising:
a plurality of first semiconductor chips, each comprising a first lower pad and a first upper pad opposite to each other, and a through-via connecting the first lower pad and the first upper pad; and
a second semiconductor chip on an uppermost first semiconductor chip,
among the plurality of first semiconductor chips, the second semiconductor chip comprising a second lower pad connected to the through-via;
an upper cover member on the chip stack;
an intermediate insertion member between the upper cover member and the chip stack;
a dam structure on the base chip on a side surface of the chip stack;
a molded layer on at least a portion of each of the chip stack, the intermediate insertion member, the upper cover member, and the dam structure on the base chip; and
a connection bumps below the base chip and connected to the lower connection terminal,
wherein the first lower pad included in each of the plurality of first semiconductor chips is in contact with the upper connection terminal included in the base chip in the first direction or the first upper pad included in each of the plurality of first semiconductor chips in the first direction,
wherein the second lower pad of the second semiconductor chip is in contact with the first upper pad of the uppermost first semiconductor chip in the first direction,
wherein the intermediate insertion member has a lower surface in contact with the second semiconductor chip, an upper surface in contact with the upper cover member, and a side surface between the lower surface and the upper surface,
wherein at least a portion of the side surface of the intermediate insertion member is curved,
wherein a height of the dam structure in the first direction is greater than a height of the chip stack in the first direction, and
wherein a thickness of the upper cover member in the first direction is greater than a thickness of each of the plurality of first semiconductor chips in the first direction and a thickness of the second semiconductor chip in the first direction.

2. The semiconductor package of claim 1, wherein an upper surface of the dam structure is spaced apart from the upper surface of the intermediate insertion member by a first distance in the first direction, and
wherein an internal surface of the dam structure is spaced apart from the side surface of the chip stack by a second distance in a second direction, perpendicular to the first direction.

3. The semiconductor package of claim 2, wherein a level of the upper surface of the dam structure is lower than a level of the upper surface of the intermediate insertion member in the first direction.

4. The semiconductor package of claim 2, wherein the first distance is less than or equal to 10 μm, and
wherein the second distance is less than or equal to 100 μm.

5. The semiconductor package of claim 1, wherein the intermediate insertion member is insulated from the chip stack.

6. The semiconductor package of claim 1, wherein the dam structure comprises a plurality of dam structures spaced apart from each other and facing the side surface of the chip stack.

7. The semiconductor package of claim 1, wherein the dam structure continuously faces the side surface of the chip stack.

8. The semiconductor package of claim 1, wherein the dam structure comprises a plurality of dam structures sequentially spaced apart from each other in a direction normal to the side surface of the chip stack.

9. The semiconductor package of claim 8, wherein the plurality of dam structures comprises an internal dam structure on the side surface of the chip stack, and an external dam structure farther from the chip stack than the internal dam structure.

10. The semiconductor package of claim 1, wherein a thickness of the intermediate insertion member in the first direction is less than the thickness of the second semiconductor chip.

11. The semiconductor package of claim 1, wherein a width of the upper cover member in a second direction, perpendicular to the first direction, is less than a width of the intermediate insertion member in the second direction.

12. The semiconductor package of claim 1, wherein the intermediate insertion member and the upper cover member comprise silicon (Si).

13. The semiconductor package of claim 1, wherein each of the plurality of first semiconductor chips further comprises a first lower insulating layer on the first lower pad, and a first upper insulating layer on the first upper pad,
wherein the second semiconductor chip further comprises a second lower insulating layer on the second lower pad,
wherein the base chip further comprises a dielectric layer on the upper connection terminals,
wherein the first lower insulating layer included in each of the plurality of first semiconductor chips is in contact with the dielectric layer included in the base chip in the first direction or the first upper insulating layer included in each of the plurality of first semiconductor chips in the first direction, and
wherein the second lower insulating layer included in the second semiconductor chip is in contact with the first upper insulating layer included in the uppermost first semiconductor chip.

14. The semiconductor package of claim 13, wherein the first lower insulating layer, the first upper insulating layer, the second lower insulating layer, and the dielectric layer comprise at least one of silicon oxide (SiO) and silicon carbon nitride (SiCN).

15. A semiconductor package, comprising:
a base chip comprising a through-electrode;
a plurality of first semiconductor chips stacked on the base chip in a first direction and comprising a through-via connected to the through-electrode and connected to each other in the first direction;
a second semiconductor chip on an uppermost first semiconductor chip, among the plurality of first semiconductor chips, the second semiconductor chip comprising a lower pad connected to the through-via;
an intermediate insertion member and an upper cover member sequentially on the second semiconductor chip in the first direction; and
a dam structure on a side surface of each of the plurality of first semiconductor chips,
wherein an upper surface of the dam structure is spaced apart from an upper surface of the intermediate insertion member by a first distance in the first direction, and
wherein an internal surface of the dam structure is spaced apart from the plurality of first semiconductor chips by a second distance greater than the first distance in a second direction, perpendicular to the first direction.

16. The semiconductor package of claim 15, wherein a level of the upper surface of the dam structure is between a level of the upper surface of the intermediate insertion member and a level of a lower surface of the intermediate insertion member in the first direction.

17. The semiconductor package of claim 15, wherein a ratio of a width of the dam structure in the second direction to a height of the dam structure in the first direction is greater than or equal to 10%.

18. A semiconductor package, comprising:
a base chip comprising a through-electrode;
a chip stack stacked on the base chip in a first direction, the chip stack comprising:
a plurality of first semiconductor chips respectively comprising a through-via connected to the through-electrode and connected to each other in the first direction; and
a second semiconductor chip on an uppermost first semiconductor chip,
among the plurality of first semiconductor chips, the second semiconductor chip comprising a lower pad connected to the through-via;
an intermediate insertion member and an upper cover member sequentially on the chip stack in the first direction; and
a dam structure on a side surface of the chip stack,
wherein the intermediate insertion member has a lower surface in contact with the chip stack, an upper surface in contact with the upper cover member, and a side surface between the lower surface and the upper surface, and
wherein the side surface of the intermediate insertion member comprises a first portion extending from the lower surface of the intermediate insertion member at a first slope, and a second portion extending from the first portion to the upper surface of the intermediate insertion member at a second slope less than the first slope.

19. The semiconductor package of claim 18, wherein the first portion has a first lower end connected to the lower surface of the intermediate insertion member, and a first upper end connected to the second portion, and
wherein the first portion has the first slope that is constant from the first lower end to the first upper end.

20. The semiconductor package of claim 19, wherein the second portion has a second lower end connected to the first upper end of the first portion, and a second upper end connected to the upper surface of the intermediate insertion member, and
wherein the second portion has a second slope decreasing from the second lower end to the second upper end.
